(19) United States
(12) Patent Application Publication
(10) Pub. No.: US 2009/0128152 A1
(43) Pub. Date: May 21, 2009

(54) SIMULTANEOUS MRI IMAGING OF MULTIPLE SUBJECTS

(75) Inventors: Wayne R. Dannels, Mentor, OH (US); Ivan Dimitrov, North Wales, PA (US); Christoph Leussler, Hamburg (DE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/305,429

(22) PCT Filed: Jun. 19, 2007
(86) PCT No.: PCT/US2007/071503

§ 371 Date: Dec. 18, 2008

Related U.S. Application Data
(60) Provisional application No. 60/805,500, filed on Jun. 22, 2006.

(51) Int. Cl. G01R 33/30; G01R 33/32

(52) U.S. Cl. 324/321; 324/318

(57) ABSTRACT

A magnetic resonance scanner includes a main magnet (20) that generates a static magnetic field at least in a scanning region (14), and a gradient system (26, 28) that selectively imposes selected magnetic field gradients on the static magnetic field at least in the scanning region. A structure (40) is provided for supporting a plurality of small subjects (80) in the scanning region. The structure includes a plurality of subject supports (82, 82′) each configured to support a small subject, and a plurality of solenoid coils (44, 44′, 44″) corresponding to the plurality of subject supports. Each solenoid coil is arranged with the corresponding subject support to operatively couple with a small subject supported by the corresponding subject support.

The present application relates to the magnetic resonance arts. It finds particular application in magnetic resonance imaging or spectroscopy of small animals such as mice, rats, guinea pigs, rabbits, or so forth in the context of medical research and development. However, the following will also find application in magnetic resonance imaging or spectroscopy of small animals in other contexts, and in imaging other subjects such as anatomical components (e.g., hands, feet, or so forth), or so forth that are small relative to a typical human subject.

Commercial magnetic resonance scanners are typically directed toward imaging human subjects, and accordingly have human-sized bore diameters or other imaging region dimensions sized to accommodate a human subject. Commercial nuclear magnetic resonance systems are also available for chemistry or biochemistry applications. These systems typically accommodate a small sample of predetermined size and shape, such as a test tube, probe head, or other sample container. Such systems have been adapted to perform micro-imaging of single cells or arrays of single cells. For example, Purea et al., Simultaneous NMR Microimaging of Multiple Single-Cell Samples, Concepts in Magnetic Resonance Part B (Magnetic Resonance Engineering), vol. 22B(1), pp. 7-14 (2004) disclose a probe head for a 17.6 Tesla, 89 millimeter vertical bore nuclear magnetic resonance system. The probe head included four solenoid coils each having a 2 millimeter outer diameter and configured to image a frog egg cell. The four solenoid coils were arranged in a vertical stack and were well shielded from one another by intervening horizontal copper circuit boards that doubled as substrates for the solenoid coils and their associated coil electronics.

There is also interest in performing magnetic resonance imaging or spectroscopy, or both, on small animals such as laboratory test subjects. Applications include phenotyping, drug trials, pathogen research, molecular imaging, and so forth. However, existing magnetic resonance scanners and nuclear magnetic resonance systems are typically not sized for imaging small animals. Moreover, the throughput of animals for a magnetic resonance scanner specially sized to image a small animal would be limited, which is problematic for clinical research typically involving a substantial number of small animals as test subjects.

Bock et al., U.S. Pat. No. 6,549,799 disclose a honeycomb arrangement of about two-dozen hexagonal mouse-sized cells for housing small animals in a 7 Tesla, 29 centimeter Varian Unity nuclear magnetic resonance system. Each cell includes a separately shielded 16-rung birdcage coil used in both radio frequency transmit and receive operations. Cross-talk between the closely spaced birdcage coils was identified as a critical problem, and was addressed by providing a separate shield around each birdcage coil, and by providing an active detuning loop for each coil to detune the coil when not in use. Additionally, the Bock system sequentially excites resonance in each of K sub-sets of subjects using the individual birdcage coils. Nonetheless, a coil-coil interaction of 9.8% at 5 centimeters was observed. The use of algorithms from SENSE was proposed to further compensate for cross-talk during image reconstruction.

The approach of Bock has certain disadvantages. The individual birdcage coils and attendant shielding and active detuning circuitry introduce substantial cost and increased system complexity, and yet problematic cross-talk was nonetheless measured. The strong independent shielding of each individual birdcage coil also makes it difficult or impossible to employ a common transmit coil to simultaneously excite magnetic resonance in all the subjects. Thus, the approach of Bock would likely be inoperative in conjunction with a “whole-body” transmit coil such as is sometimes included in commercial human-sized magnetic resonance scanners. Moreover, Bock's approach of sequentially exciting K sub-sets has the significant disadvantage of increased scan time, especially for acquisitions such as short repeat time (TR) three-dimensional scans with T1 weighting, which would not normally be operated with temporal interleaving.

The following discloses improvements which overcome the above-referenced problems and others.

In accordance with one aspect, a structure is disclosed for supporting a plurality of small subjects during magnetic resonance imaging or spectroscopy. A plurality of subject supports are each configured to support a small subject. A plurality of solenoid coils correspond to the plurality of subject supports. Each solenoid coil is arranged with the corresponding subject support to operatively couple with a small subject supported by the corresponding subject support.

In accordance with another aspect, a magnetic resonance scanner is disclosed. A main magnet generates a static magnetic field at least in a scanning region. A gradient system selectively imposes selected magnetic field gradients on the static magnetic field at least in the scanning region. A structure as set forth in the preceding paragraph is provided for supporting a plurality of small subjects in the scanning region, with a coil axis direction of the solenoid coils arranged generally transverse to the static magnetic field.

In accordance with another aspect, a magnetic resonance imaging method is disclosed. A plurality of small animals are loaded into subject supports of a structure that includes a plurality of subject supports each configured to support a small subject and a plurality of solenoid coils corresponding to the plurality of subject supports, in which each solenoid coil is arranged with the corresponding subject support to operatively couple with a small subject supported by the corresponding subject support. The structure is moved into an imaging region of a magnetic resonance imaging apparatus. All of the loaded small animals are imaged simultaneously using the magnetic resonance imaging apparatus.

In accordance with another aspect, an imaging system is disclosed for imaging a plurality of small subjects. A human-sized magnetic resonance scanner has a human-sized imaging volume sized to receive at least a human torso. A plurality of solenoid coils are disposed in the human-sized imaging volume. Each solenoid coil is arranged to operatively couple with a small subject.

In accordance with another aspect, an imaging method is disclosed. Magnetic resonance is simultaneously excited in a plurality of small subjects using a single transmit radio frequency coil. The excited magnetic resonance in each small subject is detected using a solenoid coil operatively coupled with the small subject. The magnetic resonance detected by each solenoid coil is reconstructed to generate a reconstructed image of the operatively coupled small subject.

One advantage resides in facilitating imaging of a plurality of small subjects using a human-sized magnetic resonance scanner, optionally including features such as automated loading and unloading of the small subjects into and out of the scanner.

Another advantage resides in facilitating performance of magnetic resonance imaging or spectroscopy on a plurality of small subjects using a “whole-body” or other human-sized radio frequency transmit coil to excite magnetic resonance in the plurality of small subjects.

Another advantage resides in providing a structure for supporting a plurality of small subjects during magnetic resonance scanning, in which the structure includes individual solenoid coils coupled with the subjects that reduce cost and system complexity.

Another advantage resides in providing a modular structure for supporting different numbers and/or arrangements of small subjects in scanner

Another advantage resides in facilitating magnetic resonance scanning of a plurality of small subjects using unshielded solenoid coils to couple with the subjects.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

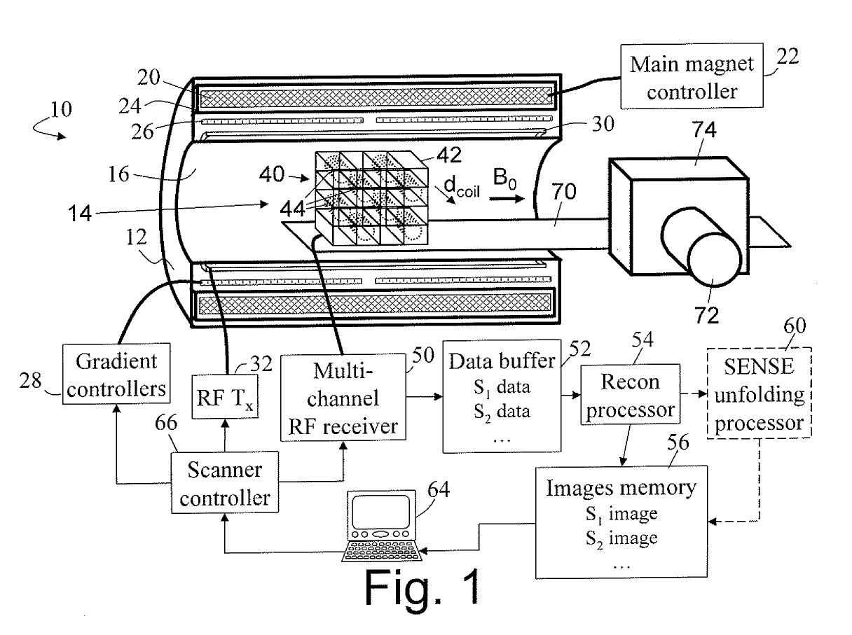

FIG. 1 diagrammatically shows a magnetic resonance system including a magnetic resonance scanner and associated electronics and a structure for supporting a plurality of small subjects in the scanner.

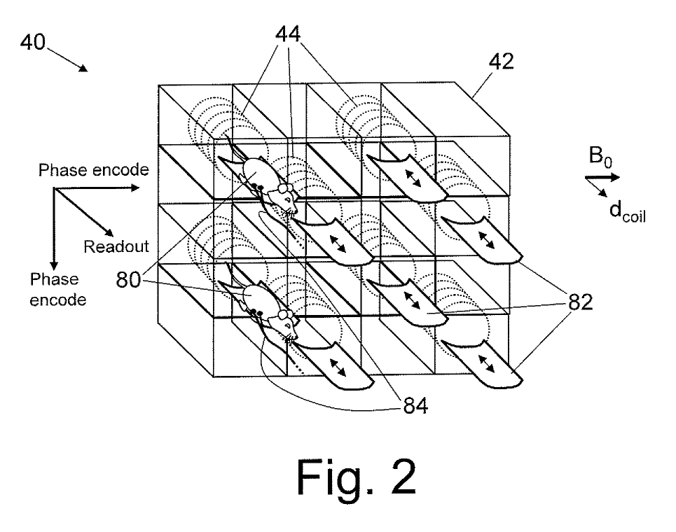

FIG. 2 diagrammatically shows the structure of FIG. 1 for supporting a plurality of small subjects in the scanner.

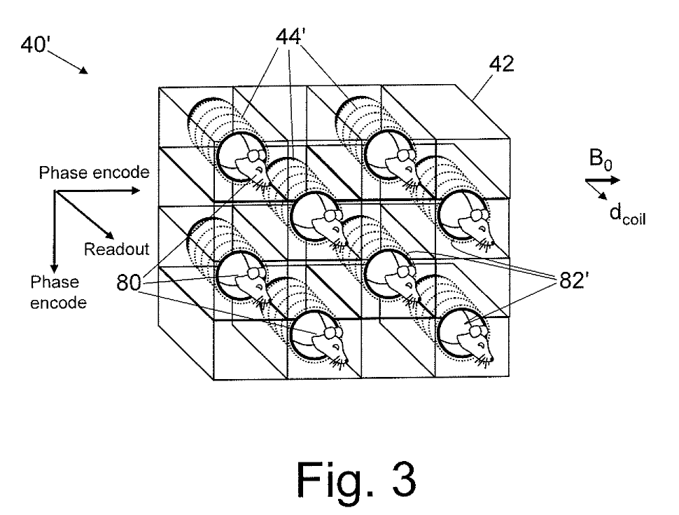

FIG. 3 diagrammatically shows another structure for supporting a plurality of small subjects in a magnetic resonance scanner.

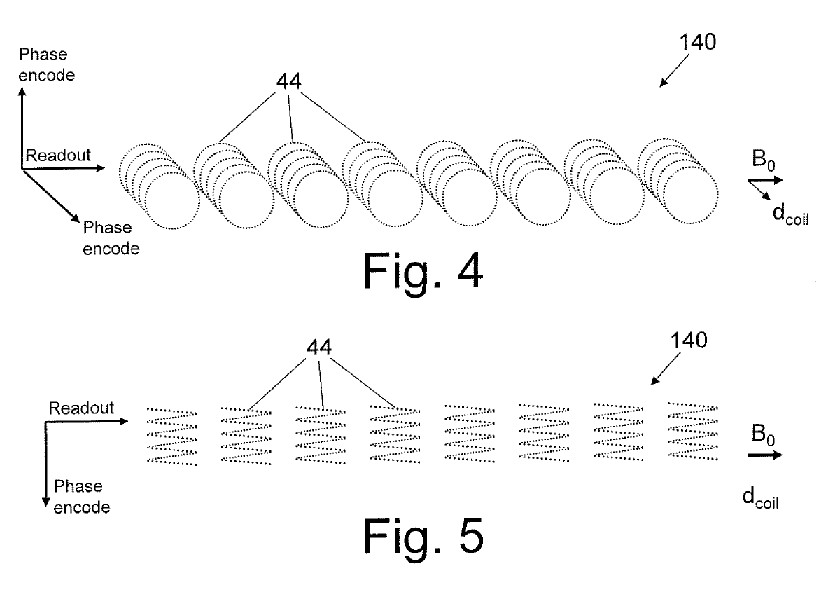

FIGS. 4 and 5 diagrammatically show perspective and top views, respectively, of a suitable one-dimensional layout for a plurality of solenoid coils for use in acquiring magnetic resonance data from a plurality of small subjects.

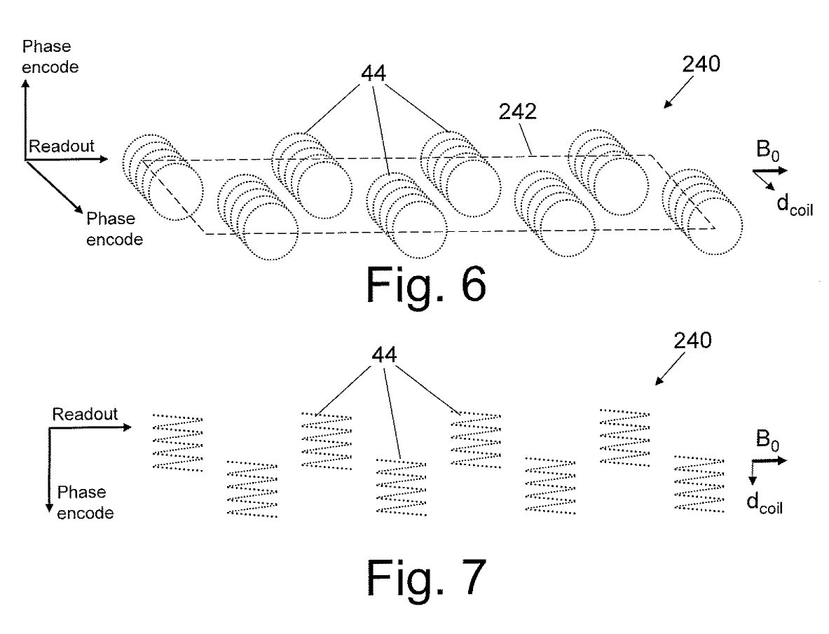

FIGS. 6 and 7 diagrammatically show perspective and top views, respectively, of a suitable staggered planar layout for a plurality of solenoid coils for use in acquiring magnetic resonance data from a plurality of small subjects.

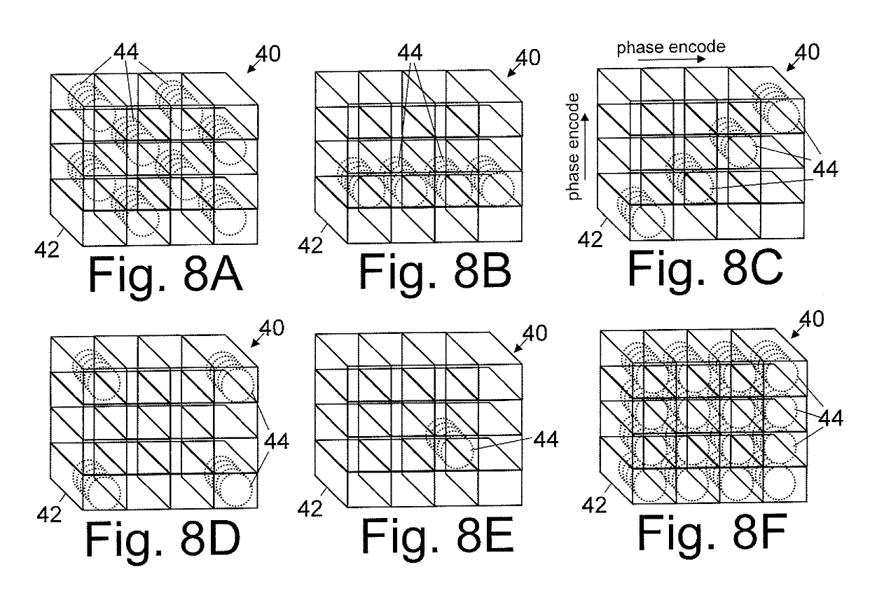

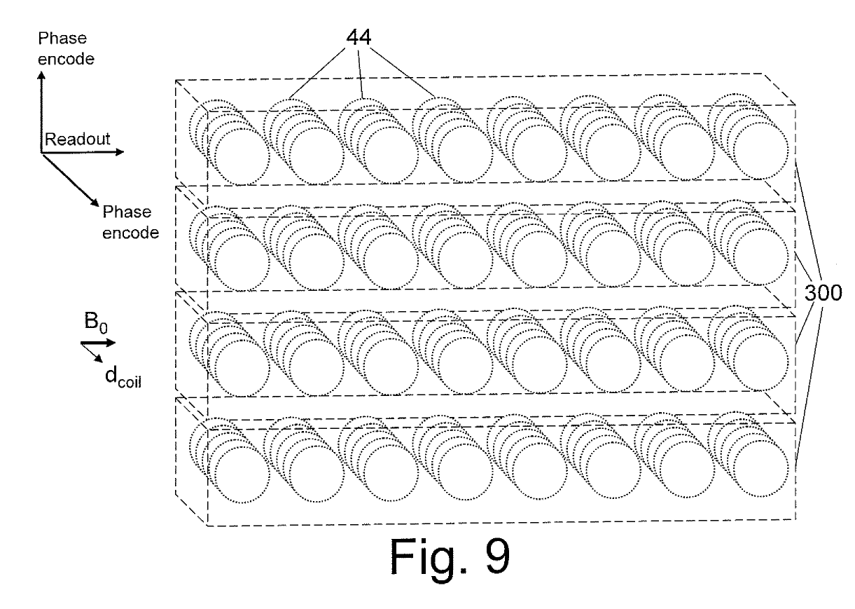

FIGS. 8A, 8B, 8C, 8D, 8E, and 8F diagrammatically show perspective views of six example layouts of small subjects in the support structure of FIG. 2.

FIG. 9 diagrammatically shows a perspective view of a thirty-two solenoid coil arrangement in which the coils are separated into four separately shielded and excited groups of eight solenoid coils each.

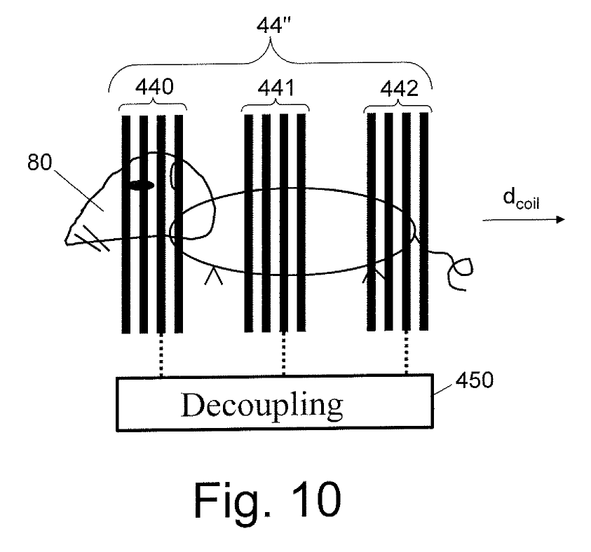

FIG. 10 diagrammatically shows a side view of a solenoid coil coupled with a small subject, in which the solenoid coil is made up of three axially aligned decoupled component solenoid coils.

With reference to FIG. 1, a human-sized magnetic resonance scanner 10 includes a scanner housing 12 defining a scanning region 14 that is sized to receive a human subject, such as a human torso, an entire human body, or so forth. Although described with reference to a bore-type scanner, it is to be appreciated that the scanner could also be an open-magnet scanner or other type of magnetic resonance scanner. Moreover, in some embodiments the scanner may be other than human-sized, such as having a scanning region substantially larger than that sufficient to scan a human subject, or having a scanning region smaller than that sufficient to scan a human subject. In the illustrated bore-type scanner, a protective insulating bore liner 16 optionally lines the bore surrounding the scanning region 14.

A main magnet 20 disposed in the scanner housing 12 is controlled by a main magnet controller 22 to generate a static (B₀) magnetic field in at least the scanning region 14. Typically, the main magnet 20 is a persistent superconducting magnet surrounded by cryoshrouding 24. In typical human-sized scanners, the main magnet 20 generates a main magnetic field of between about 0.23 Tesla and 7 Tesla, although a main magnet generating a static (B₀) magnetic field of strength less than 0.23 Tesla or higher than 7 Tesla is also contemplated. A gradient system, for example comprising magnetic field gradient coils 26 arranged around the scanning region 14 and operated by gradient controllers 28, selectively superimposes selected magnetic field gradients on the main (B₀) magnetic field in at least the scanning region 14. Typically, the magnetic field gradient coils 26 include windings configured to produce at least three orthogonal magnetic field gradients, such as orthogonal x-, y-, and z-gradients.

A transmit or transmit/receive radio frequency coil 30 is optionally mounted surrounding the scanning region 14. For a human-sized scanner, the transmit or transmit/receive coil 30 is typically a “whole-body” coil designed to excite magnetic resonance in a large portion of a human subject, such as in the torso, in the head, or in an aim or leg, or in some combination of such large anatomical parts. In some embodiments, the transmit or transmit/receive radio frequency coil 30 is a quadrature birdcage coil or a transverse electromagnetic (TEM) coil, although other types of transmit or transmit/receive coils are contemplated. A radio frequency transmitter 32 is coupled with the optional transmit or transmit/receive radio frequency coil 30 to energize the transmit or transmit/receive radio frequency coil 30 to excite magnetic resonance in subjects disposed in the scanning region 14.

A support structure 40 includes a frame 42 containing a plurality of solenoid coils 44 that are configured to receive a plurality of small subjects, such as small animals. For example, the small subjects may be mice, rats, guinea pigs, rabbits, or other types of small animals that are commonly used in clinical studies such as drug trials, pathogen research, or so forth. The solenoid coils 44 act as magnetic resonance receive coils. Each solenoid coil 44 includes one or more conductive turns (typically between one to six turns inclusive) formed around a common coil axis. The direction of the coil axis is denoted as d_{coil} herein. The solenoid coil 44 couples with (that is, generates in the case of a transmit or magnetic resonance excitation operation, or detects in the case of a magnetic resonance receive operation) a magnetic field along the coil axis. To detect magnetic resonance signals, the direction d_{coil} of the coil axis should be non-parallel to the static (B₀) magnetic field. Arranging the coil axis d_{coil} transverse to the static (B₀) magnetic field provides maximum sensitivity to the generated magnetic resonance.

Additionally, the solenoid coils 44 may also serve as transmit coils. In such embodiments, the separate transmit or transmit/receive radio frequency coil 30 is optionally omitted, and the radio frequency transmitter 32 is switchably coupled with the plurality of solenoid coils 44 via suitable switches, power splitters, phase shifters, and/or other radio frequency circuitry (not shown).

The human-sized or other large magnetic resonance scanner 10 advantageously can simultaneously scan a plurality of small animals, such as mice, rats, guinea pigs, rabbits, or so forth. In some embodiments, the scanner 10 is a commercially available human-sized magnetic resonance scanner such as an Achieva™, Panorama™, or Intera™ magnetic resonance scanner (scanners available from Koninklijke Philips Electronics N.V., Eindhoven, the Netherlands). Such a commercial scanner is designed to provide accurate imaging for medical diagnoses and the like, and provides a spatially uniform static (B₀) field, spatially uniform transmit (B₁) fields (with the optional whole-body transmit or transmit/receive radio frequency coil 30), and spatially uniform magnetic field gradients, all over a large (human-sized) scanning region 14, and further typically includes associated controls, image reconstruction software, and so forth.

A multi-channel radio frequency receiver 50 (or, equivalently, an array of single-channel radio frequency receivers) acquires magnetic resonance from the plurality of solenoid coils 44, and the data is stored in a suitable data buffer or memory 52. For example, magnetic resonance acquired by a first solenoid coil is stored as “S₁ data” in the memory 52, magnetic resonance acquired by a second solenoid coil is stored as “S₂ data” in the memory 52, and so forth. A reconstruction processor 54 reconstructs the magnetic resonance data acquired by each solenoid coil 44 to generate a reconstructed image corresponding to that coil. The reconstructed images can be stored directly in an images buffer or memory 56, for example as an “S₁ image” corresponding to the first solenoid coil, an “S₂ image” corresponding to the second solenoid coil, and so forth. Alternatively, the reconstructed images can be further processed, for example using a SENSE unfolding processor 60 that modifies each reconstructed image based on other reconstructed images to generate an improved reconstructed image, and the improved or otherwise processed reconstructed images are stored in the images buffer or memory 56.

A user interface 64 is suitably used to display selected ones or groups of the reconstructed images, for example as side-by-side comparisons to enable a user to identify differences between simultaneously imaged subjects. The user interface 64 may also enable the user to modify, render, transmit, store, or otherwise manipulate the reconstructed images. In the example embodiment shown in FIG. 1, the user interface 64 also enables the user to interact with a scanner controller 66 to operate the magnetic resonance scanner 10. In other embodiments, a separate control computer or other separate user interface may be provided to interface the user with the scanner controller 66.

In order to load and unload the small animals or other small subjects, the support structure 40 can be moved into and out of the scanning region 14, for example using a suitable conveyor 70. In some embodiments in which the scanner 10 is a commercial human-sized magnetic resonance scanner, the conveyor 70 is implemented as the couch that is typically provided with such a commercial scanner in order to load and unload human subjects. Optionally, the pallet or table of the couch is modified to securely mount or support the support structure 40. For example, sand, foam, or another damping material may be disposed on the conveyor 70, on or in the support structure 40, or elsewhere to damp mechanical vibrations caused by the gradient coils 26. As another option, the conveyor 70 can be a continuous belt, that moves the structures in one end and out the other. In some embodiments, the loading and unloading of the small animals or other small subjects into and out of the support structure 40 is partially or fully automated. The example embodiment of FIG. 1 shows one such arrangement, in which a motor 72 operates gearing 74 to move the subjects into and out of the support structure 40.

With continuing reference to FIG. 1 and with further reference to FIG. 2, the support structure 40 is further described. In the configuration of FIGS. 1 and 2, the support structure 40 contains eight solenoid coils 44 each sized to receive a single small animal, such as an illustrated mouse 80. The small subjects are loaded into the solenoid coils 44 using motorized subject support platforms 82 that are driven along the coil axis direction d_{coil} by the motor 72 and gearing 74. In FIG. 2, the subject 80 are supported separately from the solenoid coils 44. Optionally, each subject is monitored by one or more monitoring probes or sensors, such as illustrated sets of electrocardiographic (ECG) leads 84 shown in FIG. 2. The ECG signals may be used, for example, to perform retrospective cardiac gating or sorting of the magnetic resonance data so as to reconstruct for each mouse 80 an image of a selected phase of the cardiac cycle. Some other contemplated probes or sensors include: temperature sensors; blood pressure sensors; respiratory cycling monitors; and so forth. The solenoid coils 44 can include other features, such as tuning circuitry to enable reception of magnetic resonance at difference resonance frequencies (thus enabling, for example, multi-nuclear imaging such imaging of ¹⁹F and ¹H resonances). The subject supports 82 can also include other features, such as an integrated heater to keep the subjects at a controlled temperature.

In some embodiments, a plurality of the support structures 40 may be provided to enable substantially continuous usage of the scanner 10. While the subjects in one support structure are being imaged by the scanner 10, subjects previously imaged are removed from another support structure and returned to their cages or to newly cleaned cages, while a third group of subjects is being removed from their cages, fitted with probes or sensors as desired, and loaded into a third support structure preparatory to imaging. The third support structure can then be loaded into the scanner 10 as soon as the current imaging is completed.

With brief reference to FIG. 3, in an alternative support structure 40′, the same frame 42 is used to support solenoid coils. However, in the alternative support structure 40′, solenoid coils 44′ are integral with subject supports 82′ which take the form of generally cylindrical dielectric formers around which turns of the solenoid coils 44′ are wrapped. In the illustrated example, each solenoid 44′ includes five conductive turns wrapped around the dielectric former subject support 82′. The subjects 80 may, for example, be mice held frictionally within the inside of the dielectric formers 82′. Optionally, the subject supports 82′ may include end-caps (not shown) to secure the subject (such as a mouse or other small animal) in the subject support 82′. End-caps may be useful, for example, if the subject is a small animal which is alive and not sedated, or is contagious, or so forth.

With continuing reference to FIGS. 2 and 3, the solenoid coils 44, 44′ are optionally not shielded. To reduce coil-coil coupling, the solenoid coils 44, 44′ are staggered in the phase encode direction or directions so as to increase the nearest-neighbor coil spacing. Specifically, in the embodiment of FIGS. 2 and 3, the coils are staggered along two phase encode directions that are both transverse to the coil axis direction d_{coil}. The magnetic resonance readout or frequency encoding direction is along the coil axis direction d_{coil}.

When multiple coils and multiple subjects are present at once, various forms of coupling can result in degradation of the images, compared to the equivalent scanning of a single subject and a single coil. Electromagnetic noise of a thermal nature originating in one subject can be directly detected by magnetic induction into the coil associated with another subject. Thermal noise from a subject or from a first coil can be coupled into a second coil by the mutual inductance between the two coils. Magnetic resonance signal generated in a first subject can be detected in a second coil, and so forth. For high resolution imaging of small subjects, three dimensional acquisitions with small pixels involve the acquisition of large amounts of data, and hence, long scan times. To avoid substantial increase in the scan times with multiple samples, it is advantageous to collect scans in which the field-of-view along a phase encode direction of the acquisition is no larger than the field of view associated with a single subject. On the other hand, increased field-of-view along a readout gradient direction is not associated with a corresponding increase in total scan time, since higher sampling rates over the same imaging duration can typically be applied without undesirable effects. However, if the field of view in the phase encode direction is maintained at the size associated with a single subject, then signal from outside of that field of view will alias into the field of view. Aliased signal exhibits structure, and is generally less tolerable in the final image than increases in thermal noise. For example, a coupling mechanism in which additional coils introduce a few percent of uncorrelated thermal noise energy may be deemed negligible, but a coupling of magnetic resonance encoded signal at the level of a few percent from additional coils spaced apart along a phase encode direction may produce image artifacts that substantially interfere with interpretation of the images. Accordingly, reduction or removal of couple signal along an imaging phase encoded direction is advantageous in a multiple subject imaging system.

More generally, the signal-to-noise ratio for magnetic resonance data acquisition may be substantially unaffected by the spacing of coils along the readout or frequency encoding direction. On the other hand, the signal coupling is increased and image quality in the form of an image-to-artifact ratio is degraded when the coil spacing along a phase encoding direction is reduced. If SENSE encoding algorithms are performed by the SENSE unfolding processor 60 along the phase encoding direction, then the undersampling in the phase encoding direction further exasperates the signal-to-noise ratio degradation due to coil-coil coupling or due to mutual sensitivity along the phase encoding direction. This SENSE-specific signal-to-noise degradation is referred to as “the g-factor” in the literature. Accordingly, the layout of the solenoid coils should be such that the spacing of coils along the phase encoding direction is large. Typically, it is also desirable for the coil axis direction d_{coil} to be generally transverse to the static (B₀) magnetic field, so as to provide maximal coupling between the solenoid coils 40, 44 and the magnetic resonance signals.

With reference to FIGS. 4 and 5, in one suitable layout the solenoid coils 44 define a one-dimensional array 140 arranged parallel with the static (B₀) magnetic field and transverse to the coil axis direction d_{coil}. The readout or frequency encoding direction is along the one-dimensional array 140 where the coil spacing is small. On the other hand, the phase encode direction or directions are arranged substantially transverse to the one dimensional array 140. Accordingly, the “spacing” between coils along the phase encoding direction is effectively infinite (that is, the solenoid coils have no nearest neighbor coils along the phase encoding direction or directions).

With reference to FIGS. 6 and 7, in another suitable layout 240 the solenoid coils 44 are staggered in a plane 242 that is parallel with both the static (B₀) magnetic field and the coil axis d_{coil}. The readout or frequency encoding direction is along the B₀ direction and transverse to the coil axis direction d_{coil}. Suitable phase encode directions include the coil axis direction d_{coil}, and/or the direction transverse to both the B₀ direction and the coil axis direction d_{coil}. In both of these directions, there are no neighboring coils, and so coil-coil coupling along these suitable phase encode directions is small.

In both example layouts 140, 240 shown in FIGS. 4-7, imaging is assumed to use non-spatially selective magnetic resonance excitation followed by a readout sequence that employs phase encoding in two directions. Alternatively, a slice-selective magnetic resonance excitation can be employed, in which the slice-select direction is transverse to the phase encoding and frequency encoding directions. In other embodiments, non-Cartesian spatial encoding can be employed, such as spiral encoding of k-space. If SENSE is employed, then the layout should be selected such that the coil-coil spacing along the undersampled direction or directions is large or infinite (for example, one-dimensional in the undersampled direction). It will be appreciated that suitable layouts may depend upon the number of small subjects being simultaneously scanned.

With reference to FIGS. 8A, 8B, 8C, 8D, 8E, and 8F, the illustrated example support structure 40 is modular, with the frame 42 having recesses or openings and modular units each including one of the solenoid coils 44 (or alternatively one of the solenoid coils 44′) and a corresponding frame 82 (or alternatively a corresponding frame 82′) being disposed in selected recesses or openings of the frame 42 to define a selected spatial arrangement of subjects. FIG. 8A shows the staggered layout also shown in FIGS. 1 and 2. FIG. 8B shows a one-dimensional layout similar to that of FIGS. 4 and 5, but involving only four subjects. FIG. 8C shows another layout, with two suitable phase encode directions indicated. (For each of FIGS. 8A-8F, the coil axis direction d_{coil} is also a suitable phase encode direction, since the layouts of FIGS. 8A-8F are one-dimensional in the coil axis direction d_{coil}.) FIG. 5D shows another layout, which provides larger spacing for only four subjects. FIG. 5E shows that the modular support structure 40 can accommodate a single subject if desired. FIG. 8F shows the modular support structure 40 with all sixteen available recesses or openings filled. The frame 42 includes a 4×4 rectangular array of recesses that can be selectively filled by the solenoid coils 44. In other embodiments, the array can be larger or smaller, can have different dimensions (a 4×8 array, for example), can be non-rectangular (a honeycomb-type hexagonal array, for example), can include two or more layers along the coil axis direction d_{coil} (for example, to accommodate layouts such as the staggered layout 240 shown in FIGS. 6 and 7), or so forth.

In embodiments such as those of FIGS. 2-7, substantial reduction in coil-coil coupling is achieved by judicious layout of the solenoid coils 44, 44′. In some cases, these coil layouts provide nearest-neighbor coil-coil coupling in the phase encode direction of less than or about 1% for unshielded solenoid coils. With such low coil-coil coupling, it is typically sufficient to reconstruct the magnetic resonance data from each solenoid coil independently to produce reconstructed images. In general, as more subjects are scanned simultaneously, the minimum coil spacing becomes smaller. For example, in the arrangement of FIG. 5F only the coil axis direction d_{coil} has large (infinite) coil spacing. In some cases, the nearest-neighbor coil-coil signal coupling between solenoid coils may be between about 5% and about 10% inclusive for unshielded solenoid coils with suitable spacing in the phase encode direction. For coil coupling in this range, SENSE can be employed by the SENSE unfolding processor 60 along the phase encode direction having the enhanced (e.g., 5% to 10%) coupling to improve the reconstructed images of the small subjects. In general, since the signal-to-noise ratio component for coil-coil signal coupling in the readout direction is negligible, the coil spacing in the readout direction can be smaller than the coil spacing in the one or more phase encode directions so as to increase the packing of subjects.

If the number of small subjects to be simultaneously imaged is sufficiently large, then unshielded solenoid coils may experience too much coil-coil coupling. In these cases, the solenoid coils can be shielded. To promote modularity, it is contemplated for such shielding to be electronically detunable to turn the shielding on or off for different scanning applications. Shielding individual solenoid coils may interfere with the magnetic resonance excitation provided by the transmit or transmit/receive radio frequency coil 30 optionally mounted surrounding the scanning region 14, since the shielding will be disposed between the subject and the transmit coil 30. If the solenoid coils are used for magnetic resonance excitation, this is not a problem.

With reference to FIG. 9, in another approach a plurality of one-dimensional arrays of solenoid coils are each surrounded by a shield/transmit coil assembly 300. In this way, the one-dimensional arrays are shielded from one another along the phase encode direction, and by having each one-dimensional array separately excited by its shield/transmit coil assembly 300 the shielding does not adversely affect magnetic resonance excitation. Advantageously, the layout of FIG. 9 enables thirty-two solenoid coils to be operated simultaneously with only four transmit channels. In contrast, if each solenoid coil is used to excite magnetic resonance in its associated subject, then thirty-two transmit channels are required. (It will be appreciated that multiple transmit channels can be driven by the single radio frequency transmitter 32 using suitable power splitters and so forth; however, the amount of high-power radio frequency circuitry generally increases with the number of channels). FIG. 9 shows stacking of one-dimensional arrays along a direction transverse to both the B₀ direction and the coil axis direction d_{coil}. However, similar stacking can be performed along the coil axis d_{coil} direction. A plurality of modules can also be placed side-by-side. The solenoid coils can be axially offset from coils of a neighboring module or radio frequency screening can be disposed between neighboring modules.

It has been reported (Haase et al., NMR Probeheads for In Vivo Applications, Concepts in Magnetic Resonance vol. 12(6), pp. 361-88 (2000)) that the optimal solenoid coil has a length that is about 80% of the coil diameter. Accordingly, a subject with a relatively large length:width ratio may extend substantially outside the length of the optimal solenoid coil. The portions of the subject extending outside the length of the solenoid coil may experience less accurate scanning.

With reference to FIG. 10, in one approach for addressing a subject having a relatively large length:width ratio, a solenoid coil 4411 (which is suitably substituted for one of the solenoid coils 44 or for one of the solenoid coils 44′) is divided into two or more axially aligned component solenoid coils 440, 441, 442. Because the component solenoid coils 440, 441, 442 are close to one another, coil-coil coupling between the component solenoid coils 440, 441, 442 is controlled using a decoupling network 450, which may include for example small decoupling series transformers, decoupling shunt capacitors, decoupling loops disposed between the component solenoid coils 440, 441, 442, or so forth. Additionally or alternatively, SENSE performed by the SENSE unfolding processor 60 can be used to mathematically reduce artifacts due to coil-coil coupling between the component solenoid coils 440, 441, 442.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A structure for supporting a plurality of small subjects during magnetic resonance imaging or spectroscopy, the structure comprising:
a plurality of subject supports each configured to support a small subject; and
a plurality of solenoid coils corresponding to the plurality of subject supports, each solenoid coil arranged with the corresponding subject support to operatively couple with a small subject supported by the corresponding subject support.

2. The structure as set forth in claim 1, wherein each subject support defines a small animal receiving region and the corresponding solenoid coil peripherally surrounds the subject support.

3. The structure as set forth in claim 1, further including:
a transmit or transmit/receive radio frequency coil surrounding the plurality of solenoid coils and configured to excite magnetic resonance in any small subjects supported by the plurality of subject supports.

4. The structure as set forth in claim 1, wherein each solenoid coil of the plurality of solenoid coils includes two or more axially aligned component solenoid coils.

5. The structure as set forth in claim 1, wherein each solenoid coil is unshielded.

6. The structure as set forth in claim 1, wherein each solenoid coil is unshielded, and the solenoid coils are arranged such that nearest-neighbor coil-coil signal coupling in a phase encode direction is less than or about 1%.

7. The structure as set forth in claim 1, wherein the solenoid coils are arranged with relatively larger nearest-neighbor spacing in a phase encode direction and relatively smaller nearest-neighbor spacing in a readout direction.

8. The structure as set forth in claim 1, wherein the solenoid coils are arranged staggered along a phase encode direction to substantially reduce nearest-neighbor coil-coil coupling.

9. The structure as set forth in claim 1, wherein the subject supports include generally cylindrical dielectric formers each supporting one or more conductive turns of the corresponding solenoid coil.

10. The structure as set forth in claim 1, further including:
a frame having recesses or openings, the solenoid coils being disposed in selected recesses or openings of the frame to define a selected spatial arrangement.

11. The structure as set forth in claim 10, wherein the frame is sized to be received in a human-sized scanning region of a human-sized magnetic resonance scanner.

12. The structure as set forth in claim 1, wherein each solenoid coil includes between one and six conductive turns inclusive.

13. A magnetic resonance scanner comprising:
a main magnet for generating a static magnetic field at least in a scanning region;
a gradient system for selectively imposing selected magnetic field gradients on the static magnetic field at least in the scanning region; and
a structure as set forth in claim 1 for supporting a plurality of small subjects in the scanning region, with a coil axis direction of the solenoid coils arranged generally transverse to the static magnetic field.

14. A magnetic resonance imaging method comprising:
loading a plurality of small animals into subject supports of the structure as set forth in claim 1;
moving the structure into an imaging region of a magnetic resonance imaging apparatus; and
imaging all of the loaded small animals simultaneously using the magnetic resonance imaging apparatus.

15. The magnetic resonance imaging method as set forth in claim 14, wherein the imaging includes:
simultaneously exciting and manipulating magnetic resonance in the small animals with a whole-body radio frequency coil of the imaging apparatus;
applying magnetic field gradients simultaneously across the small animals with whole-body magnetic field gradient coils of the imaging apparatus;
receiving magnetic resonance signals from each small animal with one or more of the solenoid coils corresponding to each small animal; and
reconstructing the magnetic resonance signals from the solenoid coils into an image of each small animal.

16. An imaging system for imaging a plurality of small subjects, the imaging system comprising:
a human-sized magnetic resonance scanner having a human-sized imaging volume sized to receive at least a human torso; and
a plurality of solenoid coils disposed in the human-sized imaging volume, each solenoid coil arranged to operatively couple with a small subject.

17. The imaging system as set forth in claim 16, wherein the solenoid coils are arranged with a coil axis direction generally transverse to a direction of a static magnetic field generated by the human-sized magnetic resonance scanner.

18. The imaging system as set forth in claim 16, wherein the human-sized magnetic resonance scanner includes:
a human-sized whole body radio frequency transmit or transmit/receive coil arranged to excite magnetic resonance in the small subjects operatively coupled with the plurality of solenoid coils.

19. The imaging system as set forth in claim 16, further including:
a reconstruction processor that reconstructs magnetic resonance data acquired by each solenoid coil to generate a corresponding reconstructed image.

20. The imaging system as set forth in claim 19, wherein the solenoid coils are arranged such that nearest-neighbor coil-coil signal coupling in an undersampled phase encode direction is between about 5% and about 10% inclusive and a SENSE unfolding processor is provided to modify each reconstructed image based on other reconstructed images to generate an improved reconstructed image.

21. An imaging method comprising:
simultaneously exciting magnetic resonance in a plurality of small subjects using a single transmit radio frequency coil;
detecting the excited magnetic resonance in each small subject using a solenoid coil operatively coupled with the small subject; and
reconstructing the magnetic resonance detected by each solenoid coil to generate a reconstructed image of the operatively coupled small subject.

22. The imaging method as set forth in claim 21, wherein the reconstructing includes:
reconstructing two or more folded images of each small subject from magnetic resonance detected by two or more component solenoid coils of the solenoid coil operatively coupled with the small subject; and
combining the folded images of each small subject into an unfolded reconstructed image of the small subject.

23. The imaging method as set forth in claim 21, further including:
before the exciting of magnetic resonance, loading a plurality of the small animals into the structure of claim 1; and
moving the structure into an imaging region with coil directional axes generally transverse to a static magnetic field.
